(19) United States
(12) Patent Application Publication
(10) Pub. No.: US 2025/0248183 A1
(43) Pub. Date: Jul. 31, 2025

(54) DISPLAY DEVICE

(71) Applicant: AUO Corporation, Hsinchu City (TW)

(72) Inventors: Hung-Yin Chen, Hsinchu City (TW); Chun-Hsiang Chan, Hsinchu City (TW); Sheng-Ming Huang, Hsinchu City (TW); Ching-Liang Huang, Hsinchu City (TW); Li-Kai Chia, Hsinchu City (TW)

(73) Assignee: AUO Corporation, Hsinchu City (TW)

(21) Appl. No.: 18/826,205

(22) Filed: Sep. 6, 2024

(30) Foreign Application Priority Data
Jan. 30, 2024 (TW) 113103475

(51) Int. Cl. H01L 33/60; H01L 25/16

(52) U.S. Cl. CPC H10H 20/856; H01L 25/167

(57) ABSTRACT

A display device includes a driving substrate, a plurality of light-emitting elements, a seed layer, a metal layer, and an insulating layer. The plurality of light-emitting elements are electrically connected to the driving substrate. The seed layer is disposed on the driving substrate and located between the plurality of light-emitting elements. The metal layer is disposed on the seed layer, wherein the metal layer surrounds the light-emitting elements. The insulating layer surrounds the light-emitting element and contacts the metal layer and a sidewall of the light-emitting elements respectively.

### CROSS-REFERENCE TO RELATED APPLICATION

This application claims the priority benefit of Taiwan application serial no. 113103475, filed on Jan. 30, 2024. The entirety of the above-mentioned patent application is hereby incorporated by reference herein and made a part of this specification.

### BACKGROUND

### Technical Field

The disclosure relates to an electronic device, and in particular relates to a display device.

### Description of Related Art

A micro light-emitting diode panel includes an active element substrate and a micro light-emitting diode (micro LED) on the active element substrate, and is electrically connected to the drive circuit layer in the active element substrate. Micro LED panels have become the focus of research and development by major manufacturers due to their high brightness, high resolution and high contrast.

However, in the application of high-pixel displays (e.g., augmented reality display devices (AR) or virtual reality displays (VR)), the pixel density is usually above 2000 PPI (pixels per inch). Due to the small pixel pitch (typically less than 5 microns (μm) apart), it is challenging to increase the thickness of the light blocking layer between multiple micro light-emitting diodes. For example, the thickness of the white bank used as a light blocking layer is usually around 15 microns, and its light-shielding effect is also limited. Therefore, light emitted by adjacent micro light-emitting diodes easily affect each other and cause optical cross talk. This results in poor resolution or color performance, thereby reducing the quality of the image display screen. How to effectively address the aforementioned issues remains a challenge to be resolved by the relevant manufacturers.

### SUMMARY

A display device that can effectively prevent optical cross talk problems, improve the resolution, contrast and color saturation of a display screen, and achieve good display image quality, is provided in the disclosure.

The display device of the disclosure includes a driving substrate, multiple light-emitting elements, a seed layer, a metal layer, and an insulating layer. The light-emitting elements are electrically connected to the driving substrate. The seed layer is disposed on the driving substrate and located between the light-emitting elements. The metal layer is disposed on the seed layer, in which the metal layer surrounds the light-emitting elements. The insulating layer surrounds each of the light-emitting elements and contacts the metal layer and a sidewall of each of the light-emitting elements respectively.

Based on the above, the display device of the disclosure uses a seed layer to generate a metal layer, thereby effectively improving the epitaxial quality of the metal layer. Consequently, this approach does not require excessive width, facilitates the achievement of a better aspect ratio, and is conducive to reducing the pixel pitch in micro light-emitting diode displays. The metal layer has high reflectivity and low transmittance for visible light bands. Therefore, compared with the low reflectivity and high transmittance of white bank for visible light, the metal layer can effectively solve the optical cross talk problem between pixels and improve the brightness and quality of the display screen. Furthermore, since the metal layer can directly contact the insulating layer on the light-emitting element, it is more conducive to heat dissipation of the light-emitting element, reducing the chance of the light-emitting element being damaged or burned due to high temperature, reducing the probability of pixel failure, and extending the service life of the light-emitting element or display device.

In order to make the above-mentioned features and advantages of the disclosure comprehensible, embodiments accompanied with drawings are described in detail below.

### BRIEF DESCRIPTION OF THE DRAWINGS

FIG. 1 is a cross-sectional schematic diagram of a display device according to an embodiment of the disclosure.

FIG. 2A to FIG. 2G are schematic diagrams of the manufacturing process of the display device of the embodiment of FIG. 1.

FIG. 3 is a cross-sectional schematic diagram of a display device according to another embodiment of the disclosure.

FIG. 4 is a cross-sectional schematic diagram of a display device according to yet another embodiment of the disclosure.

FIG. 5A to FIG. 5D are schematic diagrams of the manufacturing process of the display device of the embodiment of FIG. 4.

### DETAILED DESCRIPTION OF DISCLOSED EMBODIMENTS

The usages of “approximately”, “similar to”, “essentially” or “substantially” indicated throughout the specification include the indicated value and an average value having an acceptable deviation range, which is a certain value confirmed by people skilled in the art, and is a certain amount considered the discussed measurement and measurement-related deviation (that is, the limitation of measurement system). For example, “approximately” may indicate to be within one or more standard deviations of the indicated value, such as being within ±30%, ±20%, ±15%, ±10%, or ±5%. Furthermore, the usages of “approximately”, “similar to”, “essentially” or “substantially” indicated throughout the specification may refer to a more acceptable deviation scope or standard deviation depending on measurement properties, cutting properties, or other properties, and all properties may not be applied with one standard deviation.

In the drawings, for clarity, the thickness of layers, films, plates, areas, and the like are magnified. It should be understood that when an element such as a layer, a film, an area, or a substrate is indicated to be “on” another element or “connected to” another element, it may be directly on another element or connected to another element, or an element in the middle may exist. In contrast, when an element is indicated to be “directly on another element” or “directly connected to” another element, an element in the middle does not exist. As used herein, “to connect” may indicate to physically and/or electrically connect. Furthermore, “to electrically connect” may also be used when other elements exist between two elements.

References of the exemplary embodiments of the disclosure are to be made in detail. Examples of the exemplary embodiments are illustrated in the drawings. If applicable, the same reference numerals in the drawings and the descriptions indicate the same or similar parts.

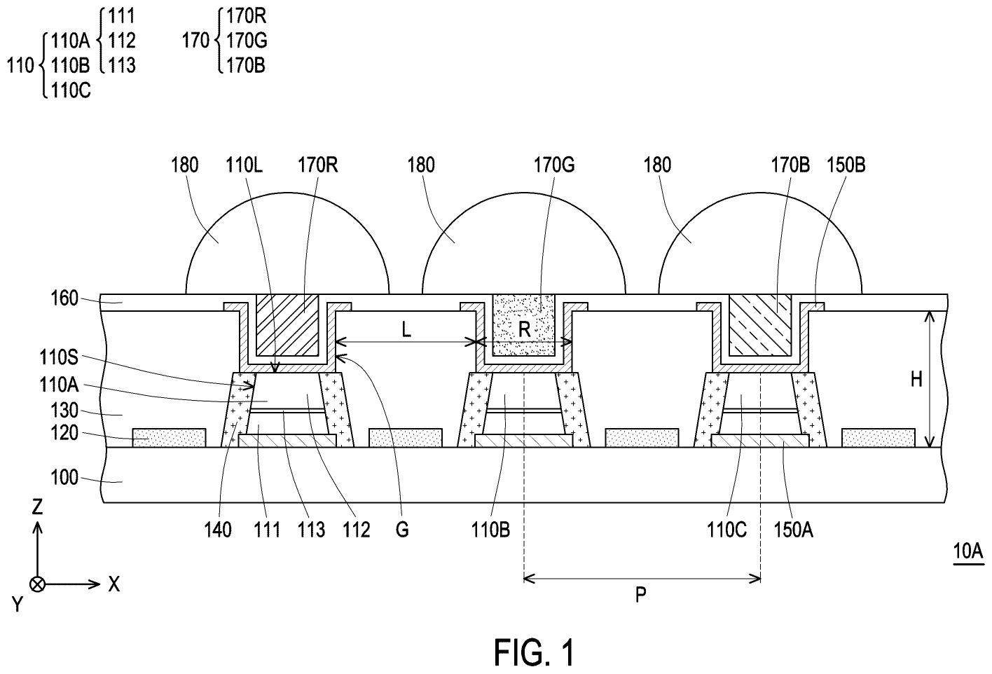

FIG. 1 is a cross-sectional schematic diagram of a display device according to an embodiment of the disclosure. Referring to FIG. 1 first, the display device 10A includes a driving substrate 100 and multiple light-emitting elements 110, such as a first light-emitting element 110A, a second light-emitting element 110B and a third light-emitting element 110C, a seed layer 120, a metal layer 130, and an insulating layer 140. The light-emitting element 110 is disposed on the driving substrate 100. The seed layer 120 is disposed on the driving substrate 100 and is located between the gaps of the light-emitting elements 110. The metal layer 130 is disposed on the seed layer 120 and surrounds the first light-emitting element 110A, the second light-emitting element 110B, and the third light-emitting element 110C on the plane formed by the direction X and the direction Y. The insulating layer 140 surrounds the light-emitting elements 110, and on the plane formed by the direction X and the direction Y, the two opposing sides of the insulating layer 140 respectively contacts the metal layer 130 and the sidewall 110s of the light-emitting element 110.

In this embodiment, the driving substrate 100 includes a variety of signal lines (e.g., data lines, scan lines or power lines, not shown) and at least one drive circuit chip (not shown). The drive circuit chip, for example, has transistors or integrated circuits (ICs) that can be electrically connected to multiple light-emitting elements 110, and controls the display signals of the light-emitting elements 110 to provide a display screen, which is not limited thereto. For example, the driving substrate 100 adopts silicon wafer material and includes complementary metal oxide semiconductor (CMOS), thereby improving the response speed of each switching element in the driving substrate 100 and reducing power consumption to meet the requirements of fast response and high resolution of the display device 10A. However, the disclosure is not limited thereto. In other embodiments, the driving substrate 100 may also be a printed circuit board (PCB). In other embodiments, the driving substrate 100 may also be a combination of a glass substrate and a pixel circuit layer. The pixel circuit layer is formed on a glass substrate by adopting a semiconductor process, and the pixel circuit layer may include active elements (e.g., thin film transistors) and various signal lines (e.g., data lines, scan lines, or power lines), but not limited thereto.

The light-emitting elements 110 may be arranged in an array in the top view direction of the display device 10A (e.g., viewed from the direction Z) to form multiple pixels of the display device 10A to generate a display image and provide a light source. In some embodiments, the light-emitting element 110 may be an ultraviolet light-emitting diode, a white light-emitting diode, a red light-emitting diode, a green light-emitting diode or a blue light-emitting diode, and is configured to provide a display light beam to form a display image. The light-emitting element 110 is, for example, a micro light-emitting diode (micro LED), a mini light-emitting diode (mini LED), or a light-emitting diode of other sizes, and the disclosure is not limited thereto. For example, the display device 10A may be a micro light-emitting diode display. On the other hand, the light-emitting element 110 may be a vertical light-emitting diode. For example, the first electrode 150A located on one side of the epitaxial structure of these light-emitting elements 110 can be used as a reflective electrode to align with the corresponding bonding pads (not shown) on the driving substrate 100, and the light-emitting element 110 and the driving substrate 100 are electrically connected to a potential (e.g., a high potential) by using surface-mount technology (SMT) or mass transfer technology to establish a bond. The second electrode 150B disposed on the light-emitting surface 110L of the light-emitting element 110 is connected to another potential (e.g., a low potential), thereby realizing the light emission of light-emitting element 110, however, the disclosure is not limited thereto. In other embodiments, the light-emitting elements 110 may also be flip-chip type light-emitting diodes, and two first electrodes 150A with different potentials located on the driving substrate 100 are used to respectively connect different pins of the flip-chip type light-emitting elements 110 to achieve electrical connection of the light-emitting elements 110.

On the other hand, the light-emitting element 110 may include a first semiconductor layer 111, a second semiconductor layer 112, and a light-emitting layer 113. The first semiconductor layer 111 may be an N-type semiconductor layer, and the second semiconductor layer 112 may be a P-type semiconductor layer, but the disclosure is not limited thereto. In addition, the first semiconductor layer 111 and the second semiconductor layer 112 may each include a multi-layer structure of a high-concentration doping layer with different doping concentrations and a semiconductor layer with a normal doping concentration. For example, the portion (e.g., the first electrode 150A) of the first semiconductor layer 111 that contacts the driving substrate 100 may include highly doped N+ gallium nitride (GaN) to facilitate ohmic contact between the first semiconductor layer 111 and the first electrode 150A. In other embodiments, other materials may also be used as the substrate material of the first semiconductor layer 111 and the second semiconductor layer 112, such as gallium arsenide (GaAs), indium gallium arsenide (InGaAs), aluminum gallium nitride (AlGaN), etc., but the disclosure is not limited thereto. In addition, the structure of the light-emitting layer 113 may be a multiple-quantum well (MQW) structure, a single quantum well structure, a double heterostructure, a single heterostructure, or a combination thereof. The disclosure is not limited thereto.

The seed layer 120 can serve as a seed layer for generating the metal layer 130 to improve the epitaxial quality of the metal layer 130 to facilitate the disposition of the metal layer 130. In some embodiments, the seed layer 120 may be composed of the same material, or may be stacked of metal layers of different materials. For example, the material of the seed layer 120 may include copper (Cu), silver (Ag), titanium (Ti), chromium (Cr), or a composite layer formed by stacking the above materials. The disclosure is not limited thereto. It is worth mentioning that the seed layer 120 and the metal layer 130 may be composed of the same material or different materials. The disclosure is not limited thereto.

The metal layer 130 can serve as a blocking wall structure between each light-emitting element 110, so that the light emitted from each light-emitting element 110 can be reflected in the metal layer 130 and transmitted toward the front viewing direction of the display device 10A (e.g., the direction Z in the figure). A portion of the metal layer 130 may contact the driving substrate 100. Preferably, the height H of the metal layer 130 on the driving substrate 100 can be greater than the height from the light-emitting surface 110L of each light-emitting element 110 to the driving substrate 100. To put it another way, the height H of the metal layer 130 is greater than the height from the light-emitting layer 113 to the driving substrate 100, so that the metal layer 130 can block the lateral light emission of the light-emitting element 110 (e.g., the light emission in the direction X and direction Y). When applied to a micro light-emitting diode display, the brightness of the micro light-emitting diode in the front viewing direction (e.g., the direction Z) can be effectively improved, and the phenomenon of optical cross talk easily occurring between each light-emitting element 110 can be further reduced. The resolution, contrast and color gamut performance of the display device 10A can be improved, and the display quality of the display device 10A can be improved. On the basis of considering improving the reflectivity and thermal conductivity, the material of the metal layer 130 can be silver (Ag), copper (Cu), aluminum (Al) or other metals, or composite materials composed of the above metal materials, and the disclosure is not limited thereto.

The insulating layer 140 is disposed between the metal layer 130 and the light-emitting elements 110 to electrically isolate the light-emitting elements 110 from each other. In some embodiments, when viewed in the top view direction of the display device 10A, the sidewalls 110s of each light-emitting element 110 may be contacted and surrounded by the insulating layer 140, and then the insulating layer 140 is contacted and surrounded by the metal layer 130. In other words, there may not be other film layers between the insulating layer 140 and the light-emitting element 110, and there may not be other film layers between the metal layer 130 and the insulating layer 140. However, the disclosure is not limited thereto. Preferably, the material of the insulating layer 140 may be an insulator material with high thermal conductivity and high resistivity, such as thermally conductive silicone, thermally conductive ceramics, silicon nitride (SiNx), silicon oxide (SiOx), silicon oxynitride (SiOxNy), or other photosensitive insulating materials or a composite structure of the above materials. However, the disclosure is not limited thereto.

To sum up, growing the metal layer 130 through electroplating of the seed layer 120 can effectively improve the epitaxial quality of the metal layer 130. When the height H of the metal layer 130 is increased, the uniformity can be effectively improved, and the metal layer 130 can readily have a larger aspect ratio. For example, the width L of the metal layer 130 may substantially be 2 microns or below. In some embodiments the width L may be between 1.5 microns and 1.8 microns. The height H of the metal layer 130 may be 6 microns or above. In some embodiments, the height H may be substantially between 7 microns and 8 microns. In summary, the ratio of the height H and the width L (i.e., the aspect ratio) of the metal layer 130 may be greater than or equal to 3 and less than or equal to 4. However, the disclosure is not limited thereto.

When the light-emitting element 110 is a vertical light-emitting diode, the metal layer 130 with high aspect ratio can be easily applied to a display with high pixel density. For example, the pitch P of the light-emitting elements 110 can be substantially 4 microns, and the size of the light-emitting openings of the light-emitting elements 110 can be appropriately sized (e.g., the aperture R can be about 2.2 microns to 2.5 microns), effectively improving the resolution and pixel density of the display device 10A, so that the display device 10A can easily meet the requirement of high resolution of near-eye displays.

As mentioned above, since metal materials have high reflectivity, low transmittance and low absorption rate, therefore, even if the metal layer 130 has a thinner thickness in the plane direction of the display device 10A due to the high aspect ratio, the light-blocking ability of the metal layer 130 is not significantly reduced compared to using a white bank as a light-shielding structure. For example, the reflectivity of the metal layer 130 in this embodiment for the visible light band (wavelength between 380 nm and 780 nm) is generally greater than 90%; the transmittance is generally less than 5%; and the absorption rate is generally less than 5%. For the white bank, in comparison, the reflectivity is generally less than 70%; the transmittance is generally greater than 15%; and the absorption rate is generally less than 15%. For the black matrix (BM), in comparison, it has low reflectivity (generally less than 2%) and high absorption rate (generally greater than 93%). Using the metal layer 130 as a light blocking layer can effectively improve the light blocking ability and the anti-optical cross talk ability, and reduce the absorption rate in the visible light band, thus greatly improving the brightness, color gamut, and resolution of the display device 10A. That is, the image quality of the displayed image is improved.

Furthermore, the thermal conductivity coefficient (W/(m*K)) of metal materials is generally high. Therefore, the design of using the metal layer 130 to contact the insulating layer 140 and then contact the light-emitting element 110 can also facilitate the heat dissipation of the light-emitting element 110, increase the service life of the light-emitting element 110, reduce the chance of pixel failure, improve the product reliability of the display device 10A, and also facilitate in enhancing the competitiveness of the product.

On the other hand, when the light-emitting element 110 is a vertical light-emitting diode, the first electrode 150A may be disposed between the driving substrate 100 and the light-emitting element 110. The second electrode 150B can be disposed on the light-emitting surface 110L of the light-emitting element 110. The first electrode 150A may be a reflective electrode and may be composed of a single metal layer or multiple metal layers. Taking a single metal layer as an example, the material of the first electrode 150A may include palladium-gold alloy, tin (Sn), silver (Ag), gold (Au), nickel-gold alloy, or organic surface protection (OSP).

The second electrode 150B may be a transparent electrode. For example, the second electrode 150B may be a transparent organic material doped with a conductive material, in which the conductive material includes one of tin dioxide, graphene, and antimony oxide. The transparent organic material includes, for example, polymers of 3,4-ethylenedioxythiophene monomer (PEDOT) and polystyrene sulfonate (PSS). Alternatively, it may include indium tin oxide (ITO), indium zinc oxide, aluminum tin oxide, aluminum zinc oxide, or other suitable oxides, or a stacked layer of at least two of the above.

On the other hand, the display device 10A may further include a protective layer 160 disposed on the second electrode 150B and the metal layer 130. The protective layer 160 is composed of, for example, a polymer with high insulation and high transmittance such as epoxy resin or optically clear adhesive (OCA), or other transparent inorganic substances, and the disclosure is not limited thereto. The protective layer 160 can prevent short circuit, block the intrusion of moisture and oxygen, and is configured to protect the underlying light-emitting element 110, the second electrode 150B, and the metal layer 130. In some embodiments, the protective layer 160 may directly contact the second electrode 150B and the metal layer 130, and further fill the groove G (described later) formed by the metal layer 130.

In addition, a color filter layer 170 may be disposed on each light-emitting element 110. For example, the color filter layer 170 may respectively include a red filter layer 170R correspondingly disposed on the first light-emitting element 110A to jointly form the red sub-pixel of the display device 10A, a green filter layer 170G correspondingly disposed on the second light-emitting element 110B to jointly form the green sub-pixel of the display device 10A, and a blue filter layer 170B correspondingly disposed on the third light-emitting element 110C to jointly form the blue sub-pixel of the display device 10A. The material of each above-mentioned filter can be conventional phosphor material, wavelength conversion material, or a quantum dot structure, etc., and the disclosure is not limited thereto.

It is worth mentioning that due to the ease of achieving a high aspect ratio in the metal layer 130, it is also feasible to control the height H of the metal layer 130, thereby facilitating the creation of sufficient accommodation space for filling filter materials to fabricate the color filter layer 170. For example, the height H of the metal layer 130 may be 3 to 4 microns greater than the height of the light-emitting surface 110L of the light-emitting element 110 to form a groove G disposed on the light-emitting surface 110L. The groove G formed by the metal layer 130 serves not only for the deposition of the second electrode 150B to electrically connect the light-emitting element 110, but also provides a space for accommodating the color filter layer 170. In other words, in the top view direction of the display device 10A, in addition to surrounding the light-emitting element 110, the metal layer 130 also further surrounds a portion of the second electrode 150B and a portion of the protective layer 160, and surrounds the red filter layer 170R, the green filter layer 170G and the blue filter layer 170B.

Based on the above, since the height H of the metal layer 130 is easily controlled through electroplating, it facilitates maintaining the consistency of the height H of the metal layer 130 (i.e., the metal layer 130 can have high flatness). As a result, the thickness of the color filter layer 170 in the direction Z can be sufficiently large, and the light beam emitted by the light-emitting element 110 can be fully converted or filtered in the color filter layer 170, which also facilitates in improving the color performance of various colored light and improving the saturation of the display screen. On the other hand, the high reflectivity and low absorption rate of the metal layer 130 can also make it difficult for the lateral emitted light beam to transmit to adjacent pixels of different colors. For example, the light beam emitted by the first light-emitting element 110A of the red pixel is easily blocked by the metal layer 130, thereby impeding the transmission to the green filter layer 170G on the adjacent second light-emitting element 110B. This can effectively reduce optical cross talk problems and effectively improve the color purity of various colored light in the display screen. In addition, the lateral emitted light beam can be reflected back and forth multiple times by the metal layer 130 in the respective color filter layers 170, effectively improving the conversion efficiency of the color filter layers 170.

On the other hand, the display device 10A may also include optical microstructures 180. The optical microstructures 180 are respectively disposed on the red filter layer 170R, the green filter layer 170G and the blue filter layer 170B, and also respectively overlap the first light-emitting element 110A, the second light-emitting element 110B and the third light-emitting element 110C.

The optical microstructure 180 is, for example, a micro converging lens, which facilitates in converging the large-angle light emitted from the light-emitting element 110. For example, when the light-emitting element 110 is a micro light-emitting diode, its field of view (FOV) is approximately 130 degrees. Through the optical effect generated by the interaction between the metal layer 130 and the optical microstructure 180, the field of view of each light-emitting element 110 can be converged to approximately 50 degrees, greatly improving the brightness from the front viewing angle. However, the disclosure is not limited thereto. In other embodiments, other shapes of optical microstructures may also be adopted to achieve the required viewing angle control. In some embodiments, the optical microstructure 180 may directly contact the protective layer 160 and each color filter layer 170. It is worth mentioning that during the formation process of the optical microstructure 180, the flatness of the supporting plane easily affects the shape of the optical microstructure 180, thereby affecting its refractive power. Since the filter layer 170 can be disposed in the groove G, and the protective layer 160 and the filter layer 170 can jointly form a flat surface on the metal layer 130 with high flatness, the optical microstructure 180 can easily form an appropriate curvature or shape, which facilitates the disposition of the optical microstructure 180 and improves reliability.

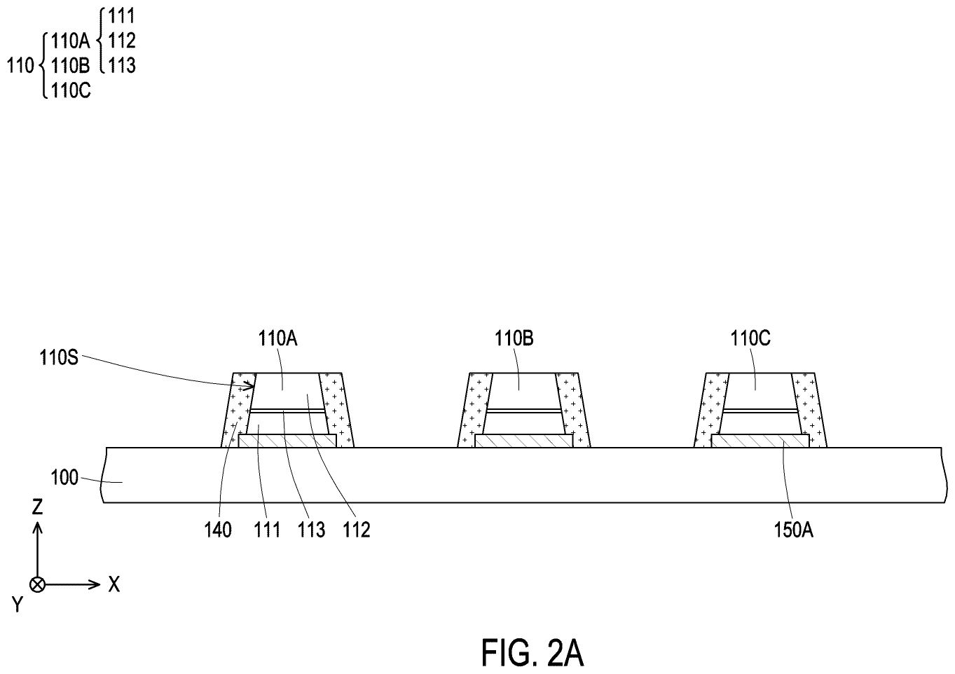

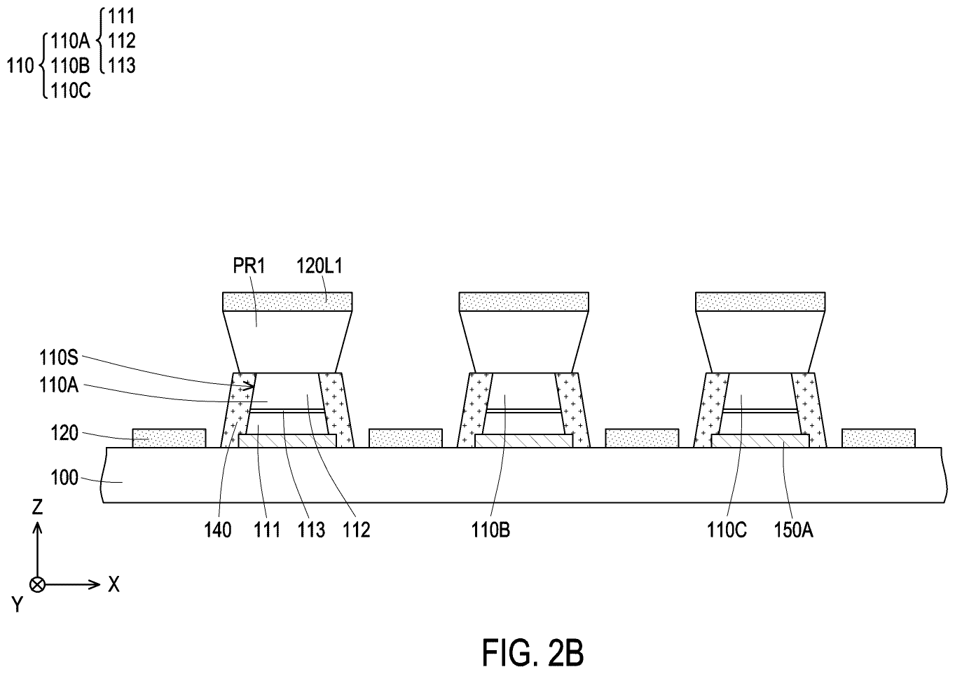

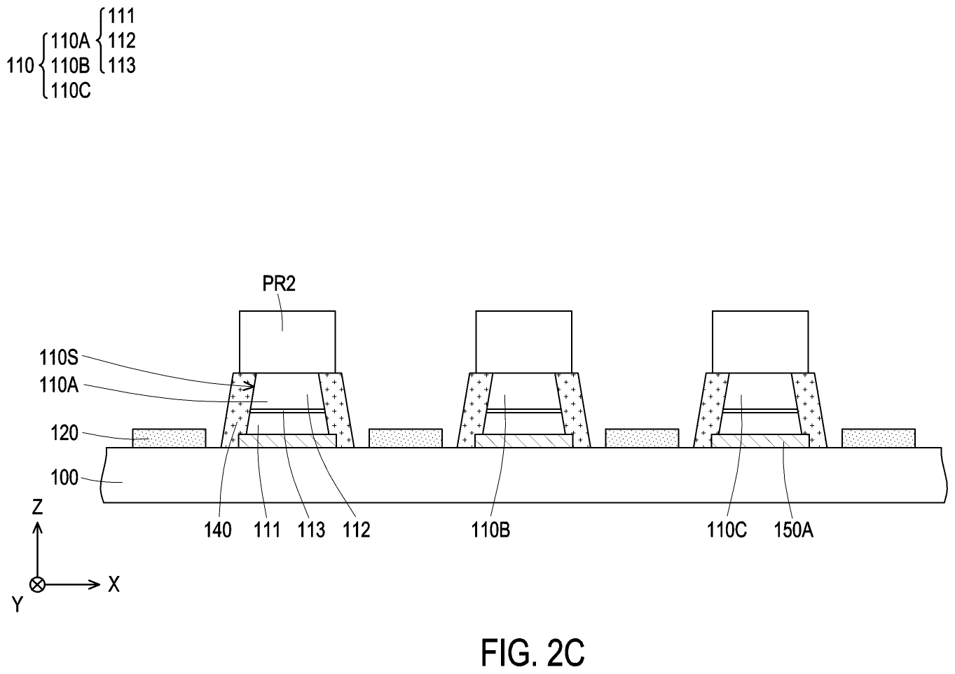

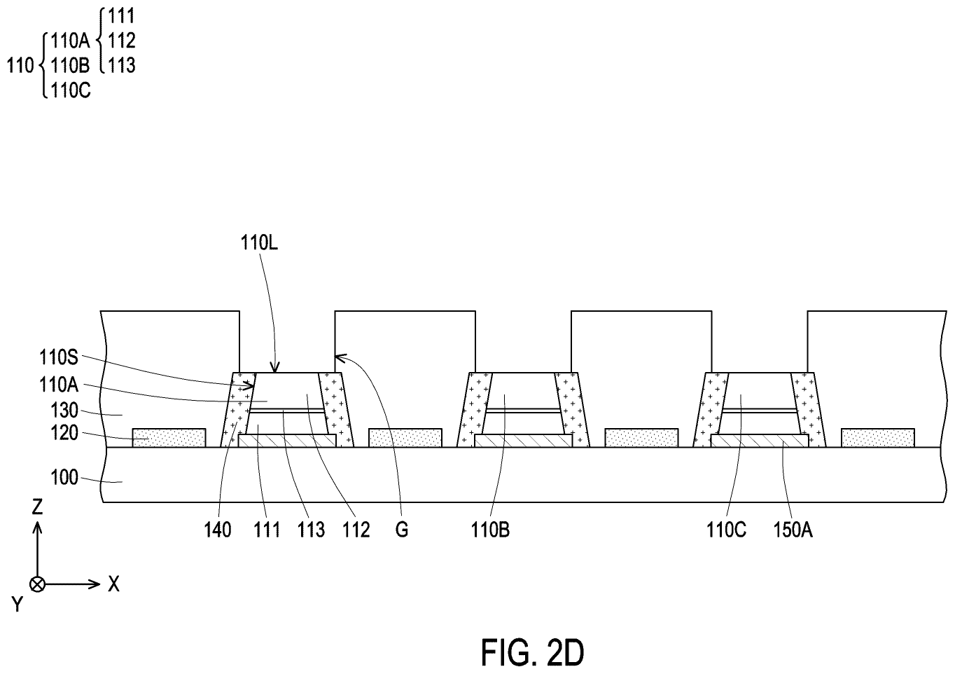

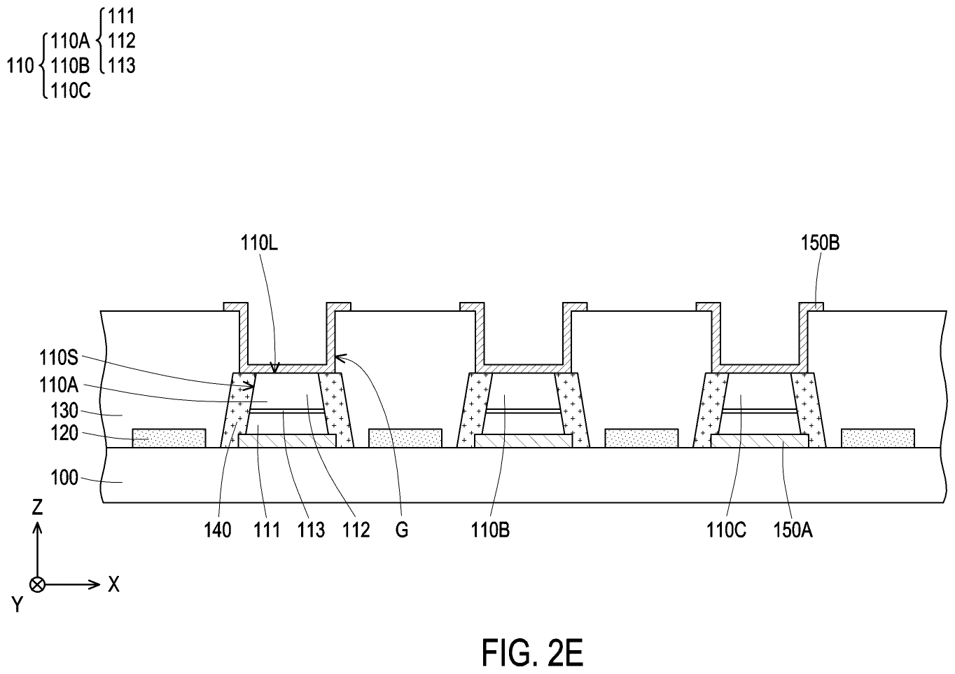

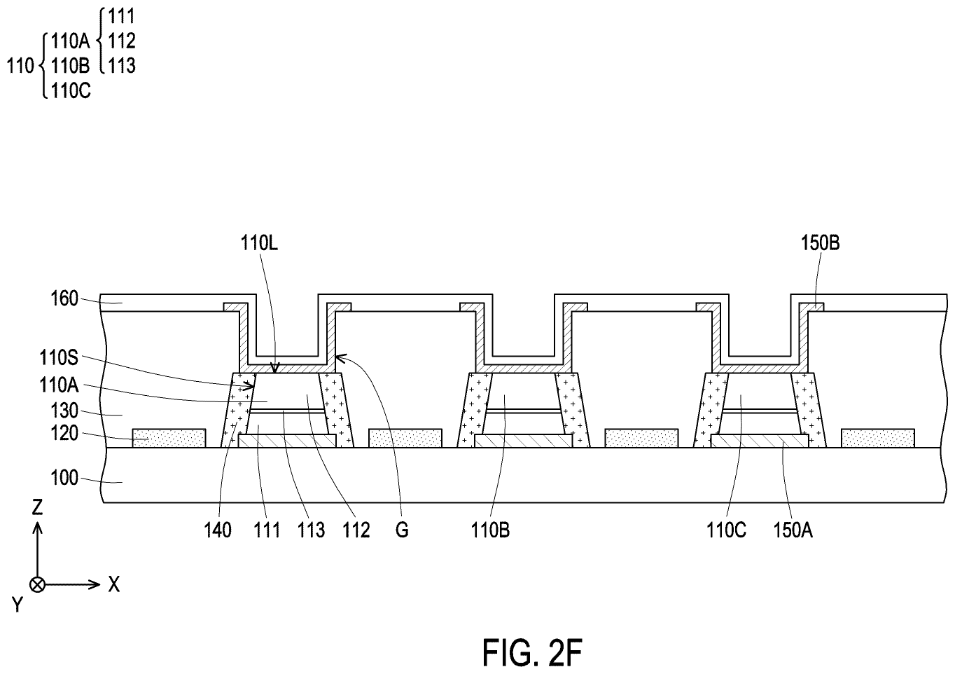

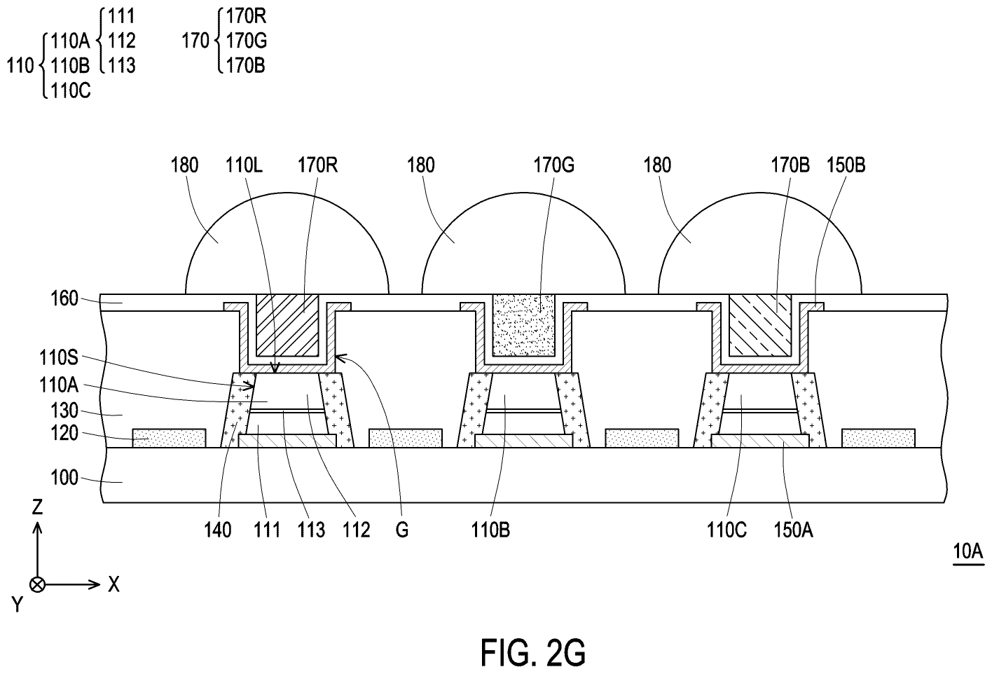

FIG. 2A to FIG. 2G are schematic diagrams of the manufacturing process of the display device of the embodiment of FIG. 1. Referring to FIG. 2A, the driving substrate 100 is first prepared, the light-emitting element 110 and the insulating layer 140 contacting the sidewall 110S are disposed on the driving substrate 100, and the first electrode 150A is used to electrically connect the driving substrate 100. For example, when the light-emitting element 110 is a micro structure, such as a micro light-emitting diode, surface bonding technology can be used to bond the first electrode 150A of the light-emitting element 110 to a pad (not shown) of the driving substrate 100. Electrostatic transfer technology, mass transfer technology or micro-transfer printing technology can be adopted to realize the transfer of the first light-emitting element 110A, the second light-emitting element 110B, and the third light-emitting element 110C. The disclosure is not limited thereto.

Referring to FIG. 2B, a coating process is then performed to form the first photoresist layer PR1, and a sputtering process and a patterning process are performed in sequence to dispose a seed layer. For example, a sputtering process may be used to form the first seed layer 120L1 deposited on the driving substrate 100 and the second seed layer 120L2 deposited on the first photoresist layer PR1. The first seed layer 120L1 and the second seed layer 120L2 do not need to be excessively thick (generally approximately 0.3 microns). A spin coating method may be used for the coating process to dispose the first photoresist layer PR1, and the first photoresist layer PR1 may be exposed, developed, and baked. The patterning process may include depositing and etching the seed layer. The first photoresist layer PR1 is disposed on each light-emitting element 110, which can achieve the purpose of protecting the light-emitting element 110.

Referring to FIG. 2C, a laser lift-off method is then used to remove the second seed layer 120L2 on the first photoresist layer PR1 to leave the first seed layer 120L1 as the seed layer 120. Then the above steps of disposing the first photoresist layer PR1 is repeated to dispose the second photoresist layer PR2. The second photoresist layer PR2 overlaps the first light-emitting element 110A, the second light-emitting element 110B and the third light-emitting element 110C respectively to achieve the purpose of protecting each light-emitting element 110 during the subsequent electroplating process.

Next, referring to FIG. 2D, an electroplating process is performed by using the seed layer 120 to generate the metal layer 130. The electroplating process is controlled so that the metal layer 130 reaches the required height and then completed. A laser lift-off process is then performed to remove the second photoresist layer PR2 to form the groove G, so that the metal layer 130 can expose the light-emitting surface 110L of each light-emitting element 110. At this point, the production of the metal layer 130 is initially completed.

Next, referring to FIG. 2E, physical vapor deposition (PVD) or chemical vapor deposition (CVD) can be used to deposit the second electrode 150B in the groove G, in which the second electrode 150B contacts the light-emitting surface 110L of the light-emitting element 110, to achieve electrical connection between the second electrode 150B and the light-emitting element 110.

Next, referring to FIG. 2F, the aforementioned deposition method (PVD or CVD) or coating method can be used to dispose the protective layer 160 to cover and contact the second electrode 150B and the metal layer 130. The protective layer 160 may be further disposed in the groove G to protect the second electrode 150B.

Next, referring to FIG. 2G, an inkjet coating method or a spin coating method can be used to respectively dispose the red filter layer 170R, the green filter layer 170G and the blue filter layer 170B in the grooves G above the first light-emitting element 110A, the second light-emitting element 110B and the third light-emitting element 110C. Then, the optical microstructure 180 is directly disposed on the red filter layer 170R, the green filter layer 170G and the blue filter layer 170B. The optical microstructure 180 may be, for example, made of photoresist material, but the disclosure is not limited thereto. Accordingly, the production of the display device 10A is initially completed.

Other embodiments are described below to explain the disclosure in detail, and the same components will be denoted by the same reference numerals, and the description of the same technical content will be omitted. For the description of the omitted part, reference may be made to the above embodiment, and details are not described in the following embodiments.

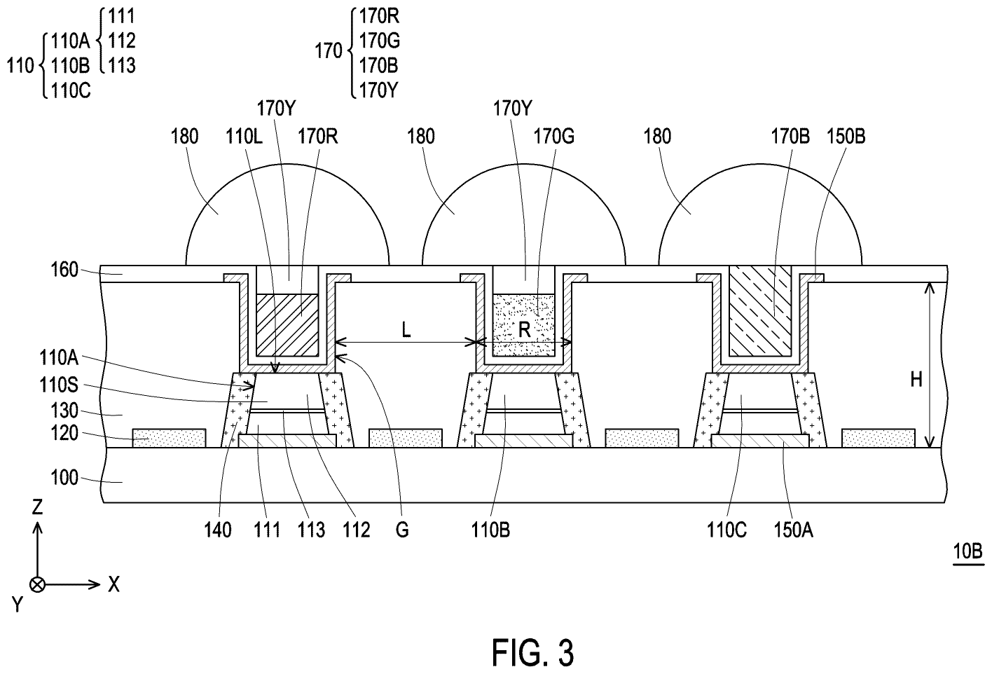

FIG. 3 is a cross-sectional schematic diagram of a display device according to another embodiment of the disclosure. Referring to FIG. 3, the display device 10B is similar to the display device 10A of FIG. 1, in which the main difference is that the disposition of the color filter layer 170 is different. In detail, the display device 10B may further include yellow filter layers 170Y, respectively disposed on the first light-emitting element 110A and the second light-emitting element 110B, respectively overlapping the red filter layer 170R on the first light-emitting element 110A and overlapping the green filter layer 170G on the second light-emitting element 110B. Of course, the disclosure is not limited thereto. In other embodiments, the yellow filter layer 170Y may also be disposed between the red filter layer 170R and the first light-emitting element 110A, and between the green filter layer 170G and the second light-emitting element 110B.

Based on the above, since the height H of the metal layer 130 can be easily increased, the height of the groove G in the direction Z can be further increased. In the case that the metal layer 130 can readily achieve a high aspect ratio, the yellow filter layer 170Y can also be easily disposed. On the other hand, when the first light-emitting element 110A, the second light-emitting element 110B and the third light-emitting element 110C are all blue light-emitting diodes, the yellow filter layer 170Y and the red filter layer 170R can jointly filter or absorb blue light, thereby further enhancing the color purity of the red light emitted by the red pixels. Similarly, the yellow filter layer 170Y and the green filter layer 170G can jointly filter or absorb blue light to further enhance the color purity of the green light emitted by the green pixels, thereby improving the color gamut and color purity of the display device 10B.

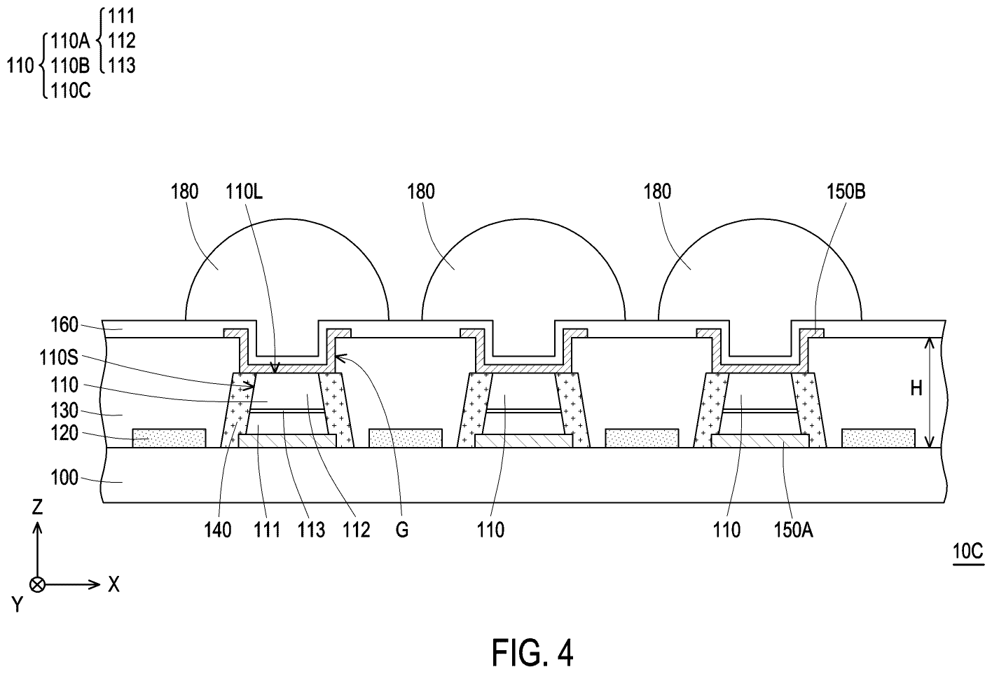

FIG. 4 is a cross-sectional schematic diagram of a display device according to another embodiment of the disclosure. Referring to FIG. 4, the display device 10C is similar to the display device 10A of FIG. 1, in which the main difference is that the display device 10C may not be provided with the color filter layer 170.

For example, each light-emitting element 110 of the display device 10C may be a single-color light-emitting diode, for example, each light-emitting element 110 may be a white-light light-emitting diode. The display device 10C can also be used as a head-up display device. Of course, the disclosure is not limited thereto.

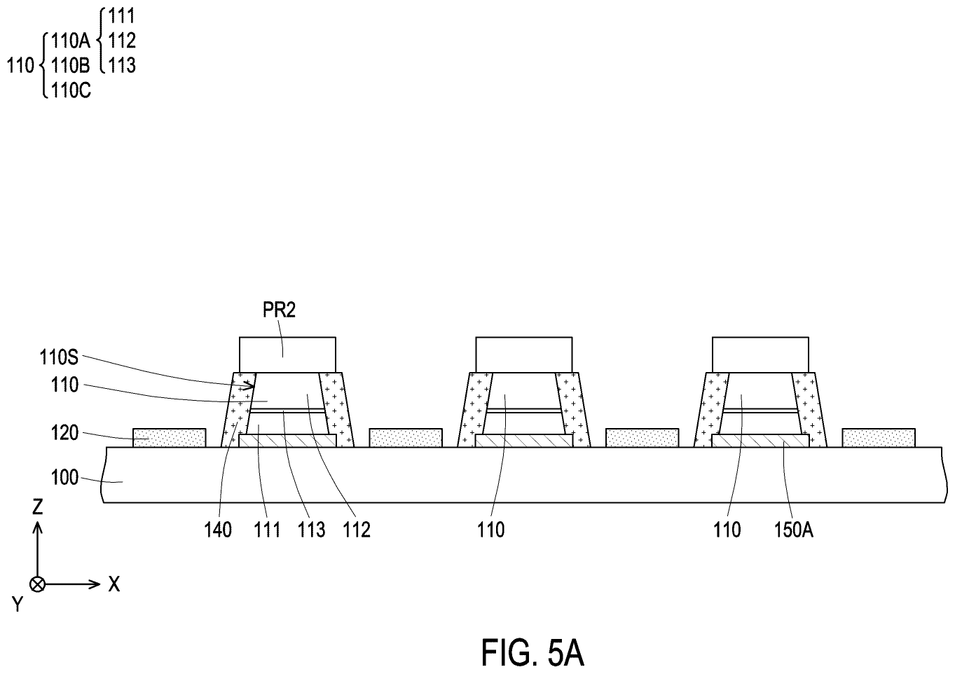

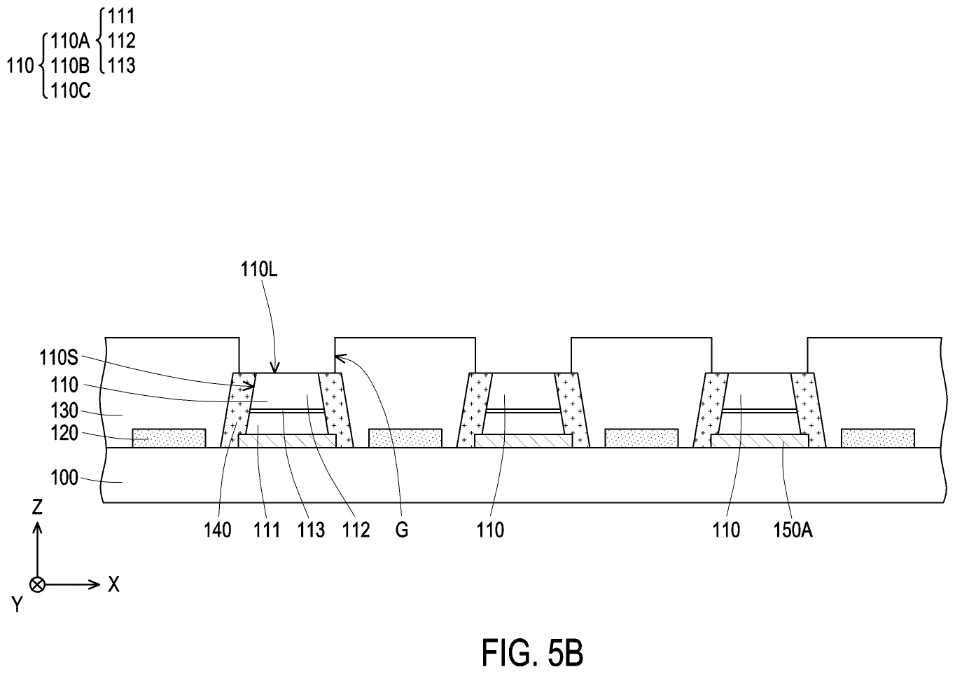

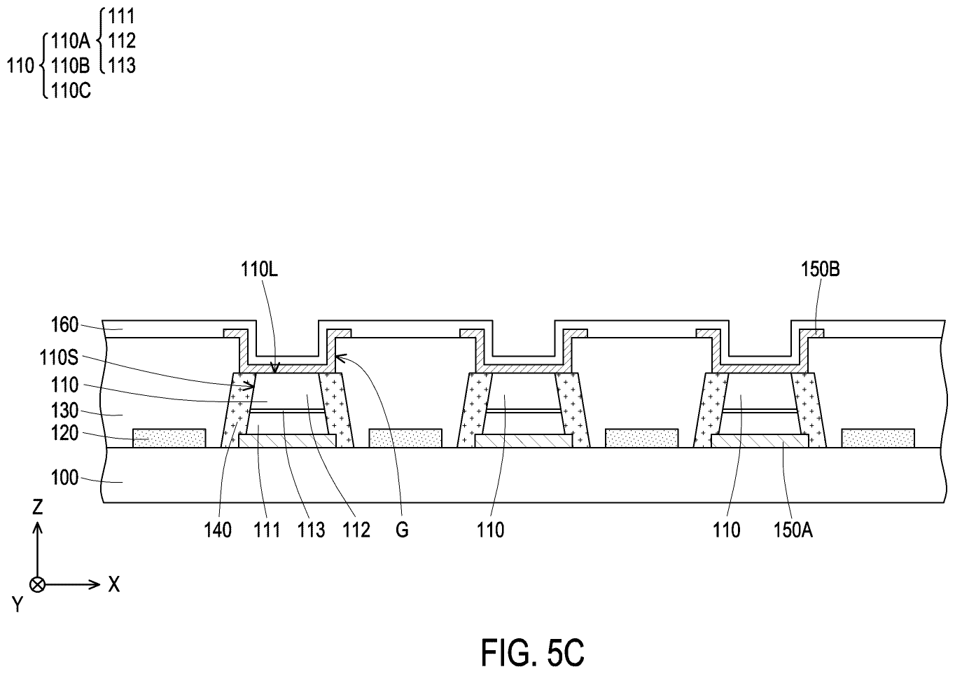

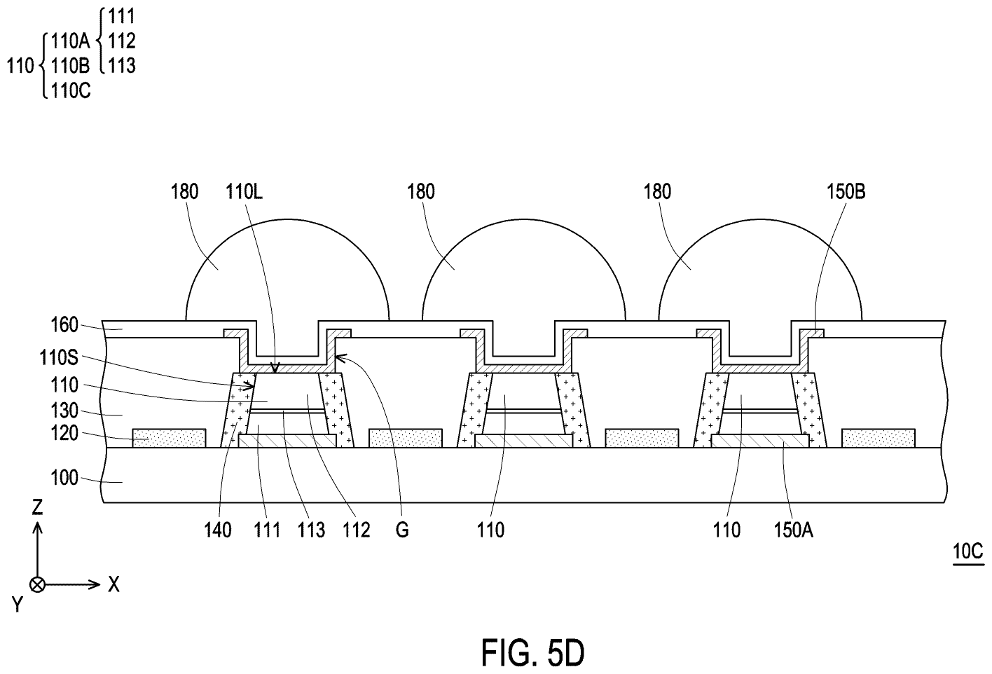

FIG. 5A to FIG. 5D are schematic diagrams of the manufacturing process of the display device of the embodiment of FIG. 4. For the steps for producing the device in FIG. 5A, reference may be made to the aforementioned process of FIG. 2A to FIG. 2B and are not repeated herein. Referring to FIG. 5A, similar to the aforementioned process of FIG. 2C, the second photoresist layer PR2 is disposed to overlap the first light-emitting element 110A, the second light-emitting element 110B and the third light-emitting element 110C respectively, to achieve the purpose of protecting each light-emitting element 110 during the subsequent electroplating process. It is worth mentioning that since the display device 10C does not need to be provided with the color filter layer 170, the metal layer 130 does not need to be excessively thick, therefore the thickness of the second photoresist layer PR2 may be less than the thickness of the second photoresist layer PR2 in FIG. 2C.

Next, referring to FIG. 5B to FIG. 5D in sequence, the metal layer 130 and the second electrode 150B are sequentially formed in the groove G on the light-emitting element 110 to electrically connect the light-emitting surface 110L; the protective layer 160 is disposed; and the optical microstructures 180 are disposed. For relevant steps other than disposing the color filter layer 170, reference can be made to the aforementioned FIG. 2D to FIG. 2G and are not repeated herein. Accordingly, the production of the display device 10C is initially completed.

To sum up, the display device of the disclosure uses a seed layer to generate a metal layer, thereby effectively improving the epitaxial quality of the metal layer. Consequently, this approach does not require excessive width, facilitates the achievement of a better aspect ratio, and is conducive to reducing the pixel pitch in micro light-emitting diode displays. The metal layer has high reflectivity and low transmittance for visible light bands. Therefore, compared with the low reflectivity and high transmittance of white bank for visible light, the metal layer can effectively solve the optical cross talk problem between pixels and improve the brightness and quality of the display screen. Furthermore, since the metal layer can directly contact the insulating layer on the light-emitting element, it is more conducive to heat dissipation of the light-emitting element, reducing the chance of the light-emitting element being damaged or burned due to high temperature, reducing the probability of pixel failure, and extending the service life of the light-emitting element or display device.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A display device, comprising:
a driving substrate;
a plurality of light-emitting elements, electrically connected to the driving substrate;
a seed layer, disposed on the driving substrate and located between the light-emitting elements;
a metal layer, disposed on the seed layer, wherein the metal layer surrounds each of the light-emitting elements; and
an insulating layer, surrounding each of the light-emitting elements and contacting the metal layer and a sidewall of each of the light-emitting elements respectively.

2. The display device according to claim 1, further comprising:
a first electrode, disposed between the light-emitting elements and the driving substrate;
a second electrode, disposed on a light-emitting surface of the light-emitting elements and electrically connected to the light-emitting surface; and
a protective layer, disposed on the second electrode and the metal layer.

3. The display device according to claim 2, further comprising:
a color filter layer, disposed on the protective layer and overlapping each of the light-emitting elements, and the metal layer surrounding the color filter layer.

4. The display device according to claim 3, further comprising:
an optical microstructure, disposed on the color filter layer and overlapping the light-emitting surface of the light-emitting elements.

5. The display device according to claim 4, wherein the optical microstructure contacts the color filter layer and the protective layer.

6. The display device according to claim 3, wherein the metal layer further surrounds a portion of the second electrode.

7. The display device according to claim 1, wherein a ratio of a height and a width of the metal layer is greater than or equal to 3 and less than or equal to 4.

8. The display device according to claim 4, wherein the color filter layer further comprises:
a yellow filter layer, a red filter layer, a green filter layer, and a blue filter layer, wherein the light-emitting elements are blue micro light-emitting diodes and comprise a first light-emitting element, a second light-emitting element and a third light-emitting element, the red filter layer is disposed on the first light-emitting element, the green filter layer is disposed on the second light-emitting element, the blue filter layer is disposed on the third light-emitting element, and the yellow filter layer is disposed on the first light-emitting element and the second light-emitting element.

9. The display device according to claim 1, wherein a color of a light emitted by the light-emitting elements are substantially the same.

10. The display device according to claim 1, wherein a portion of the metal layer further contacts the driving substrate.

11. The display device according to claim 1, wherein the first electrode is a reflective electrode and the second electrode is a transparent electrode.
